(19) United States
(12) Patent Application Publication
(10) Pub. No.: US 2010/0252930 A1
(43) Pub. Date: Oct. 7, 2010

(54) Method for Improving Performance of Etch Stop Layer

(75) Inventors: Miao-Cheng Liao, Yunlin (TW); Huai-Tei Yang, Hsin-Chu (TW); Chung-Ren Sun, Kaohsiung City (TW); Jinn-Kwei Liang, Yongkang City (TW); Ting-Xiao Liao, Tainan City (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd., Hsin-Chu (TW)

(21) Appl. No.: 12/708,160

(22) Filed: Feb. 18, 2010

Related U.S. Application Data
(60) Provisional application No. 61/165,705, filed on Apr. 1, 2009.

(51) Int. Cl. H01L 23/48; H01L 21/768

(52) U.S. Cl. 257/762; 438/637; 257/774; 257/E23.011; 257/E21.585

(57) ABSTRACT

A method of forming an interconnect structure includes providing a dielectric layer; forming a metal line in the dielectric layer; and forming a composite etch stop layer (ESL), which includes forming a lower ESL over the metal line and the dielectric layer; and forming an upper ESL over the lower ESL. The upper ESL and the lower ESL have different compositions. The step of forming the lower ESL and the step of forming the upper ESL are in-situ performed.

This application claims the benefit of U.S. Provisional Application No. 61/165,705 filed on Apr. 1, 2009, entitled “Method for Improving Performance of Etch Stop Layer,” which application is hereby incorporated herein by reference.

### TECHNICAL FIELD

This invention is related generally to integrated circuits, and more particularly to interconnect structures in integrated circuits and methods for forming the same, and even more particularly to the formation of etch stop layers.

### BACKGROUND

Integrated circuits contain a plurality of patterned metal lines separated by inter-wiring spacings. Typically, the metal patterns of vertically spaced metallization layers are electrically interconnected by vias. Metal lines formed in trench-like openings typically extend substantially parallel to the semiconductor substrate. Semiconductor devices of such type, according to current technology, may comprise eight or more levels of metallization layers to satisfy device geometry and micro-miniaturization requirements.

A common process for forming metal lines or plugs is known as “damascene.” Generally, this process involves forming an opening in the dielectric interlayer, which separates the vertically spaced metallization layers. The opening is typically formed using conventional lithographic and etching techniques. After an opening is formed, the opening is filled with copper or copper alloys to form a copper line and possibly a via. Excess metal material on the surface of the dielectric interlayer is then removed by chemical mechanical planarization (CMP).

To accurately control the formation of the damascene opening, etch stop layers are commonly used. FIG. 1 illustrates a cross-sectional view of an intermediate stage in the formation of a conventional interconnect structure. Dielectric layer 110 has copper line 112 formed therein. Composite etch stop layer (ESL) 115 includes lower layer 114 over dielectric layer 110 and metal line 112, and upper layer 116 over lower layer 114. Low-k dielectric layer 118 is formed on composite ESL 115. Opening 120 is formed in low-k dielectric layer 118. During the formation of opening 120, composite ESL 115 is used to stop the etching of low-k dielectric layer 118. Lower layer 114 is formed of nitrogen-doped silicon carbide, while upper layer 116 is formed of tetra-ethyl-ortho-silicate (TEOS) oxide.

The conventional structure as shown in FIG. 1 suffers from drawbacks. It has been found that composite ESL 115 has a poor barrier performance for preventing copper in copper line 112 from diffusing into low-k dielectric layer 118. This not only causes the degradation of low-k dielectric layer 118, but also causes the degradation of the stress migration performance of copper line 112. A solution is thus needed.

### SUMMARY OF THE INVENTION

In accordance with one aspect of the present invention, a method of forming an interconnect structure includes providing a dielectric layer; forming a metal line in the dielectric layer; and forming a composite etch stop layer (ESL), which includes forming a lower ESL over the metal line and the dielectric layer; and forming an upper ESL over the lower ESL. The upper ESL and the lower ESL have different compositions. The step of forming the lower ESL and the step of forming the upper ESL are in-situ performed.

In accordance with another aspect of the present invention, a method of forming an interconnect structure includes providing a dielectric layer having a top surface; forming a metal line extending from the top surface into the dielectric layer; forming a lower ESL including introducing a precursor and a nitrogen-containing gas into a process chamber, wherein the lower ESL is over and contacting the metal line and the dielectric layer; and forming an upper ESL over and contacting the lower ESL including continuing to introduce the precursor, wherein the nitrogen-containing gas is turned off.

In accordance with yet another aspect of the present invention, a method of forming an interconnect structure includes providing a dielectric layer; forming a metal line extending from a top surface of the dielectric layer into the dielectric layer; forming a lower ESL over and contacting the metal line and the dielectric layer; and forming an upper ESL over and contacting the lower ESL. The upper ESL has a composition different from the lower ESL. No vacuum break occurs between the step of forming the upper ESL and the step of forming the lower ESL.

In accordance with yet another aspect of the present invention, an interconnect structure includes a dielectric layer having a top surface; a metal line extending from the top surface into the dielectric layer; and a composite ESL. The composite ESL includes a lower ESL over and contacting the metal line and the dielectric layer, wherein the lower ESL includes silicon and carbon; and an upper ESL over the lower ESL, wherein the upper ESL includes silicon and carbon, and is free from nitrogen.

In accordance with yet another aspect of the present invention, an interconnect structure includes a dielectric layer; a copper line extending from a top surface of the dielectric layer into the dielectric layer; and a lower ESL over and contacting the copper line and the dielectric layer. The lower ESL is formed of nitrogen-doped silicon carbide (SiC:N). An upper ESL is over and contacting the lower ESL. The upper ESL is formed of oxygen-doped silicon carbide (SiC:O). The interconnect structure includes a low-k dielectric layer over the upper ESL; and an additional copper line and a via in the low-k dielectric layer. The additional copper line and the via are electrically connected to the copper line.

The advantageous features of the present invention include reduced manufacturing cost and cycle time, and reduced stress-migration in metal lines such as copper lines.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional interconnect structure, which comprises a composite etch stop layer (ESL); and

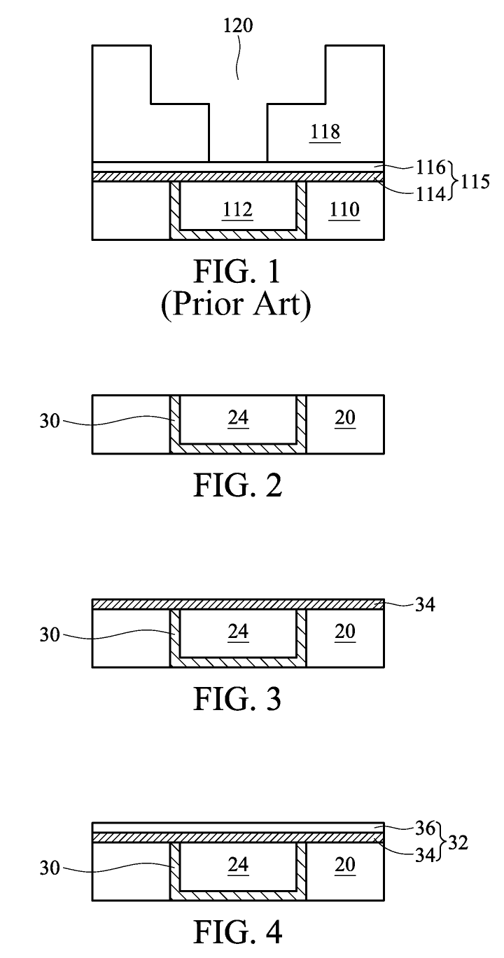

FIGS. 2 through 7 are cross-sectional views of intermediate stages in the manufacturing of an embodiment, which includes the in-situ formation of a composite ESL.

### DETAILED DESCRIPTION OF ILLUSTRATIVE EMBODIMENTS

The making and using of the embodiments of the present invention are discussed in detail below. It should be appreciated, however, that the embodiments provide many applicable inventive concepts that can be embodied in a wide variety of specific contexts. The specific embodiments discussed are merely illustrative of specific ways to make and use the invention, and do not limit the scope of the invention.

A novel interconnect structure of integrated circuits and a method of forming the same are provided. The intermediate stages of manufacturing the embodiment are illustrated. The variations of the embodiment are discussed. Throughout the various views and illustrative embodiments of the present invention, like reference numbers are used to designate like elements.

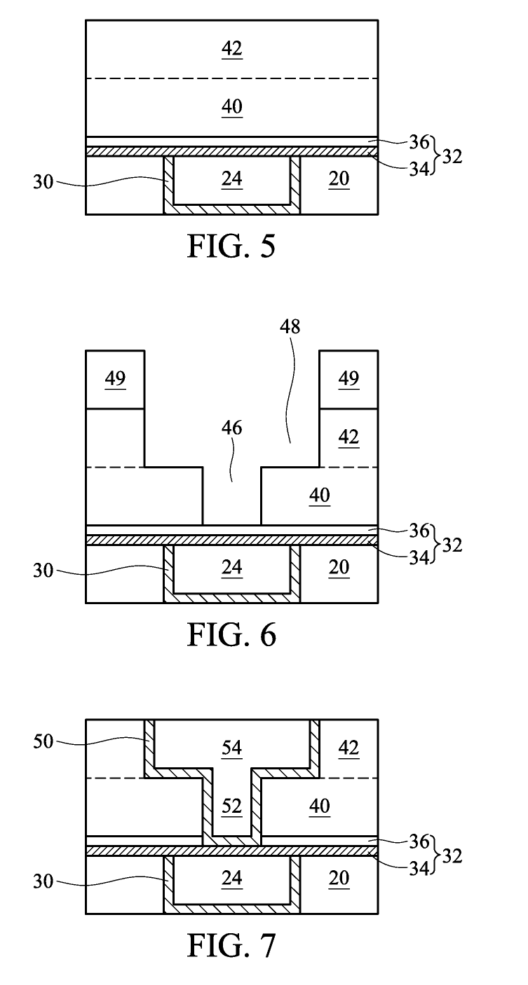

FIGS. 2 through 7 are cross-sectional views of intermediate stages in the manufacturing of an embodiment. FIG. 2 illustrates the formation of metal line 24 in dielectric layer 20, which is further formed over a semiconductor substrate (not shown). The semiconductor substrate may be a silicon substrate, or may comprise other semiconductor materials such as SiGe, GaAs, or the like. Integrated circuits such as PMOS and NMOS transistors (not shown) may be formed on the top surface of the semiconductor substrate. In an embodiment, dielectric layer 20 is an inter-metal dielectric (IMD) having a low dielectric constant value (k value), for example, lower than about 3.5. Low-k dielectric layer 20 may comprise commonly used low-k dielectric materials, such as carbon-containing dielectric materials, and may further contain nitrogen, hydrogen, oxygen, and combinations thereof.

Diffusion barrier layer 30 and metal line 24 are formed in low-k dielectric layer 20. Diffusion barrier layer 30 may include titanium, titanium nitride, tantalum, tantalum nitride, or other alternatives. The material of metal line 24 may include copper or copper alloys. Throughout the description, metal line 24 is alternatively referred to as copper line 24, although it may also be formed of, or comprise, other conductive materials, such as silver, gold, tungsten, aluminum, and the like. The steps for forming copper line 24 may include forming a damascene opening in low-k dielectric layer 20, forming diffusion barrier layer 30 in the damascene opening, depositing a thin seed layer of copper or copper alloy, and filling the damascene opening, for example, by plating. A chemical mechanical planarization (CMP) is then performed to level the surface of copper line 24, resulting in the structure as shown in FIG. 2.

FIGS. 3 and 4 illustrate the formation of composite etch stop layer (ESL) 32, which includes lower ESL 34 and upper ESL 36. Referring to FIG. 3, lower ESL 34 is formed. Lower ESL 34 may have a dielectric constant greater than about 3.5, and may comprise materials such as silicon nitride (SiN), silicon carbide (SiC), nitrogen-doped silicon carbide (SiC:N, also known as NDC), silicon oxynitride (SiON), oxygen-doped silicon carbide (SiC:O, also known as ODC), silicon oxide (SiO₂), nitrogen free anti-reflective coating layer (NFARL), titanium nitride (TiN), tantalum nitride (TaN), and combinations thereof. The formation methods may include chemical vapor deposition (CVD) methods such as plasma enhanced chemical vapor deposition (PECVD). The reaction gases (precursors) depend on the desired composition of lower ESL 34. For example, if SiN is to be formed, process gases such as NH₃ and SiH₄ may be used. If SiCN is to be formed, process gases may include CO₂, NH₃, Si(CH₃)₄ (4MS), Si(CH₃)₃H (3MS), He, N₂, Xe, and the like. If SiC is to be formed, process gases may include Si(CH₃)₄, Si(CH₃)₃H, CO₂, Xe, O₂, Xe, and the like. In addition, other precursors such as methyldiethoxysilane (mDEOS), and the precursors that are also used for forming tetra-ethyl-ortho-silicate (TEOS) may also be used. The thickness of lower ESL 34 may be between about 0.5 nm and about 100 nm. One skilled in the art will realize, however, that the dimensions recited throughout the description are merely examples, and will change if different formation technologies are used.

Next, as shown in FIG. 4, upper ESL 36 is formed on lower ESL 34. Upper ESL 36 has a composition different from that of lower ESL 34, and may be formed of nitrogen-free materials such SiC, oxygen-doped silicon carbide (SiCO, also known as ODC), or other materials that can also be used in lower ESL 34, as discussed in preceding paragraphs, and combinations thereof. Upper ESL 36 may be formed in-situ with the formation of lower ESL 34, which means that lower ESL 34 and upper ESL 36 are formed in a same process chamber. Further, no vacuum break occurs between the formation of lower ESL 34 and the formation of upper ESL 36. The deposition of lower ESL 34 and upper ESL 36 may both be performed at elevated temperatures, for example, between about 100° C. and about 500° C. However, with the in-situ formation, the respective wafer (in which the structure as shown in FIG. 3 is located) may be heated continuously, and there may be no need to cool down the wafer and heat the wafer again between the formation of lower ESL 34 and the formation of upper ESL 36. This results in less thermal budget.

The precursor for forming upper ESL 36 may include essentially the same precursors for forming lower ESL 34, except nitrogen-containing precursors are not used. The exemplary precursors may include SiH₄, Si(CH₃)₄ (4MS), Si(CH₃)₃H (3MS), methyldiethoxysilane (mDEOS), and combinations thereof. In an embodiment in which lower ESL 34 and upper ESL 36 have a common precursor, after the formation of lower ESL 34, the flow of all nitrogen-containing precursors may be turned off (and additional precursors may be added if necessary), and the deposition process is continued to form nitrogen-free upper ESL 36. The thickness of upper ESL 36 may be between about 0.5 nm and about 100 nm. Upper ESL 36 and lower ESL 34 may have a combined thickness less than about 2000 Å. In an embodiment in which upper ESL 36 is formed of SiCO, the precursor may include CO₂, Si(CH₃)₄, Si(CH₃)₃H, He, O₂, N₂, Xe and the like.

After composite ESL 32 is formed, more damascene processes may be performed to form overlying structures, for example, a via and an overlying copper line. As is known in the art, the via and its overlying copper line can be formed by either a single damascene process or a dual damascene process. Referring to FIG. 5, via IMD layer 40 is first formed over composite ESL 32. Via IMD layer 40 may be a low-k dielectric layer having a k value less than about 3.5 or an ultra low-k dielectric layer having a k value of less than about 2.7, and may comprise carbon-doped silicon oxide, fluorine-doped silicon oxide, organic low-k material and porous low-k material. The preferred formation method includes spin-on, chemical vapor deposition (CVD) or other known methods. Trench IMD 42 is then formed over via IMD layer 40. Trench IMD 42 may be formed using similar methods and similar materials as via IMD layer 40. Optionally, an etch stop layer (not shown) may be formed on via IMD layer 40 prior to forming trench IMD 42. Trench IMD 42 and via IMD layer 40 may by formed of porous materials.

Referring to FIG. 6, via opening 46 and trench opening 48 are formed. The formation of via opening 46 and trench opening 48 may be assisted by photo resists for defining patterns. FIG. 6 illustrates photo resist 49 for defining the pattern of trench opening 48. It is observed that upper ESL 36 is nitrogen free, and hence the adverse effects of nitrogen to the photo resist (known as PR poison) is substantially eliminated since upper ESL 36 prevents nitrogen in lower ESL 34 from being released to photo resist 49. Particularly, upper ESL 36 may also prevent the nitrogen in lower ESL 34 from poisoning the photo resist (not shown) when via opening 46 is formed. Photo resist 49 is then removed.

In subsequent process steps, as shown in FIG. 7, the exposed portion of composite ESL 32 is etched, followed by the formation of diffusion barrier layer 50. The remaining via opening 46 and trench opening 48 are then filled with conductive materials such as copper or copper alloys. A chemical mechanical polish (CMP) is then performed to remove excess materials. The remaining portion of the conductive material forms conductive line 54 and via 52.

Experiments have revealed that composite ESL 32 has excellent barrier performance for preventing the copper in copper line 24 from diffusing to via IMD layer 40. Secondary ion mass spectrometry (SIMS) results have revealed that substantially no copper is diffused from copper line 24 to via IMD layer 40 if composite ESL 32 comprises a nitrogen-doped carbide lower layer and an oxygen-doped carbide upper layer. As a comparison, if a composite ESL including a nitrogen-doped carbide lower layer and a TEOS upper layer is used, the SIMS results have revealed that a substantial amount of copper diffuses from copper line 24 into via IMD layer 40.

The embodiments of the present invention have several advantageous features. By in-situ forming lower ESL 34 and upper ESL 36 (refer to FIG. 4), the manufacturing cost may be reduced by about 30 percent as compared to ex-situ forming lower ESLs and upper ESLs. The cycle time is also reduced. With upper ESL 36 having a composition close to that of lower ESL 34, the adhesion between lower ESL 34 and upper ESL 36 is improved. The etch process selectivity is also increased.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps. In addition, each claim constitutes a separate embodiment, and the combination of various claims and embodiments are within the scope of the invention.

What is claimed is:

1. A method of forming an interconnect structure, the method comprising:
providing a dielectric layer;
forming a metal line in the dielectric layer; and
forming a composite etch stop layer (ESL) comprising:
forming a lower ESL over the metal line and the dielectric layer; and
forming an upper ESL over the lower ESL, wherein the upper ESL and the lower ESL have different compositions, and wherein the step of forming the lower ESL and the step of forming the upper ESL are in-situ performed.

2. The method of claim 1, wherein the lower ESL comprises nitrogen, and wherein the upper ESL is nitrogen-free.

3. The method of claim 2, wherein the lower ESL comprises nitrogen-doped silicon carbide (SiC:N).

4. The method of claim 2, wherein the upper ESL comprises oxygen-doped silicon carbide (SiC:O).

5. The method of claim 1, wherein the interconnect structure is not cooled down between the step of forming the lower ESL and the step of forming the upper ESL.

6. The method of claim 1 further comprising:
forming a low-k dielectric layer over the composite ESL; and
forming an additional metal line and a via in the low-k dielectric layer, wherein the additional metal line and the via are electrically connected to the metal line.

7. The method of claim 1, wherein the step of forming the lower ESL comprises introducing a precursor and a nitrogen-containing gas into a process chamber, and wherein the step of forming the upper ESL comprises continuing to introduce the precursor and turning off the nitrogen-containing gas.

8. The method of claim 1, wherein a precursor selected from the group consisting essentially of SiH₄, Si(CH₃)₄ (4MS), Si(CH₃)₃H (3MS), methyldiethoxysilane (mDEOS), and combinations thereof is used in both the step of forming the lower ESL and the step of forming the upper ESL.

9. A method of forming an interconnect structure, the method comprising:
providing a dielectric layer comprising a top surface;
forming a metal line extending from the top surface into the dielectric layer;
forming a lower etch stop layer (ESL) comprising introducing a precursor and a nitrogen-containing gas into a process chamber, wherein the lower ESL is over and contacting the metal line and the dielectric layer; and
forming an upper ESL over and contacting the lower ESL comprising continuing to introduce the precursor, wherein the nitrogen-containing gas is turned off.

10. The method of claim 9, wherein the lower ESL comprises nitrogen, and the upper ESL comprises oxygen.

11. The method of claim 10, wherein the lower ESL comprises nitrogen doped silicon carbide (SiC:N), and the upper ESL comprises oxygen doped silicon carbide (SiC:O).

12. The method of claim 9 further comprising:
forming a low-k dielectric layer over the upper ESL; and
forming an additional metal line and a via in the low-k dielectric layer, wherein the additional metal line and the via are electrically connected to the metal line.

13. A method of forming an interconnect structure, the method comprising:
providing a dielectric layer;
forming a metal line extending from a top surface of the dielectric layer into the dielectric layer;
forming a lower etch stop layer (ESL) over and contacting the metal line and the dielectric layer; and
forming an upper ESL over and contacting the lower ESL, wherein the upper ESL has a composition different from the lower ESL, and wherein no vacuum break occurs between the step of forming the upper ESL and the step of forming the lower ESL.

14. The method of claim 13, wherein no wafer cooling down is performed between the step of forming the upper ESL and the step of forming the lower ESL.

15. The method of claim 13, wherein the lower ESL comprises nitrogen and is oxygen-free, and wherein the upper ESL comprises oxygen and is nitrogen-free.

16. The method of claim 15, wherein the lower ESL comprises nitrogen-doped silicon carbide (SiC:N), and wherein the upper ESL comprises oxygen-doped silicon carbide (SiC:O).

17. The method of claim 13, wherein the lower ESL is formed of silicon carbide (SiC), and wherein the upper ESL comprises oxygen-doped silicon carbide (SiC:O).

18. An interconnect structure comprising:
a dielectric layer comprising a top surface;
a metal line extending from the top surface into the dielectric layer; and
a composite etch stop layer (ESL) comprising:
a lower ESL over and contacting the metal line and the dielectric layer, wherein the lower ESL comprises silicon and carbon; and
an upper ESL over the lower ESL, wherein the upper ESL comprises silicon and carbon, and is free from nitrogen.

19. The interconnect structure of claim 18, wherein the upper ESL comprises oxygen-doped silicon carbide (SiC:O).

20. The interconnect structure of claim 18, wherein the lower ESL further comprises nitrogen (SiC:N).

21. The interconnect structure of claim 18, wherein the upper ESL contacts the lower ESL.

22. The interconnect structure of claim 18 further comprising:
a low-k dielectric layer over the composite ESL; and
an additional metal line and a via in the low-k dielectric layer, wherein the additional metal line and the via are electrically connected to the metal line.

23. An interconnect structure comprising:
a dielectric layer;
a copper line extending from a top surface of the dielectric layer into the dielectric layer;
a lower ESL over and contacting the copper line and the dielectric layer, wherein the lower ESL is formed of nitrogen-doped silicon carbide (SiC:N);
an upper ESL over and contacting the lower ESL, wherein the upper ESL is formed of oxygen-doped silicon carbide (SiC:O);
a low-k dielectric layer over the upper ESL; and
an additional copper line and a via in the low-k dielectric layer, wherein the additional copper line and the via are electrically connected to the copper line.

24. The interconnect structure of claim 23, wherein the upper ESL contacts the low-k dielectric layer.

25. The interconnect structure of claim 23, wherein the upper ESL and the lower ESL have a combined thickness of less than about 2000 Å.
